(19) United States
(12) Patent Application Publication
(10) Pub. No.: US 2021/0280628 A1
(43) Pub. Date: Sep. 9, 2021

(54) METHOD FOR CONNECTING CROSS-COMPONENTS AT OPTIMISED DENSITY

(71) Applicant: Commissariat A L'Energie Atomique et aux Energies Alternatives, Paris (FR)

(72) Inventors: François MARION, SAINT-MARTIN-LE VINOUX (FR); Lydie MATHIEU, POMMIERS-LA-PLACETTE (FR); Frédéric BERGER, SAINT-MARCELLIN (FR)

(21) Appl. No.: 16/325,095

(22) PCT Filed: Aug. 18, 2017
(86) PCT No.: PCT/FR2017/052247

§ 371 Date: Feb. 12, 2019

(30) Foreign Application Priority Data
Aug. 18, 2016 (FR) 16 01237

(51) Int. Cl. H01L 27/146

(52) U.S. Cl. CPC H01L 27/14636; H01L 27/1469; H01L 27/14634

(57) ABSTRACT

A method for electrical connection by hybridisation of a first component with a second component. The method comprises the following steps: forming pads of ductile material in contact respectively with connection zones of the first component; forming inserts of conductive material in contact with the connection zones of the second component; forming hybridisation barriers arranged between the inserts and electrically insulated from each other, the first and second hybridisation barriers serving as a barrier by containing the deformation of the pads of ductile material during the connection of the connection zones of the first component with those of the second component. The disclosure also relates to an assembly of two connected components.

### TECHNICAL FIELD

The invention relates to the field of micro-electronics and optoelectronics and relates more particularly to methods for interconnecting microelectronic and optoelectronic components and particularly vertical connection methods (also known as “hybridisation” and better known as “flip-chip”).

The invention thus relates to a method for interconnecting two components and an assembly comprising two interconnected components.

### STATE OF THE PRIOR ART

For some applications, particularly optoelectronics, it may be necessary to interconnect components. This is particularly the case for light detection applications wherein the light capture component is generally integrated in a III-V semiconductor substrate, such as a gallium nitride GaN substrate, whereas the processing electronics for processing the signals obtained by the capture components are integrated in the silicon Si substrate.

To interconnect these components, it is known to use vertical or hybridisation connection methods. During the use of a method according to these methods and for the connection of a first and a second component, the first and second component include respectively a first and a second connection face, the first connection face including at least a first and a second connection zone to be connected respectively to at least a third and a fourth corresponding zone of the second connection face. The method includes the following steps:

formation of a first and a second ductile material bump, such as a first and second indium bead, in respective contact with the first and the second connection zone,

formation of a third and a fourth ductile material bump, such as a third and a fourth indium bead, in respective contact with the third and the fourth connection zone,

connection of the first and the second connection zone with respectively the third and the fourth connection zone, the first and second connection zones facing the third and fourth connection zones and the connection being made by thermocompression.

So as to lower the temperature used during the connection and reduce the distance between the contact zones to thus increase the density of the connections, it is known from the documents WO2006/054005 and WO2009/115686 to provide instead of the third and fourth ductile material bumps, a first and a second insert in contact respectively with the third and fourth connection zone.

In this way, during the step of connecting the first and second connection zones with the third and fourth connection zones, the first and the second insert will have a contact surface that is relatively small and suitable for being inserted into corresponding ductile material bump. This makes it possible to significantly reduce the temperature and pressure requirements for obtaining such an insertion. It is therefore possible to reduce the temperature and the pressure used during thermocompression and therefore control the compression of the ductile material bump optimally.

Nevertheless, even with such control of the compression of the ductile material bump, the density of the connections that can be obtained by means of such a connection method remains limited. Indeed, in the case of a conventional design of ductile material bumps of 3.5 μm in diameter and of micro-tube type inserts, as disclosed in the document WO2009/115686, of a diameter of 2 82 m, it is necessary to have a pitch between the connection zones greater than 5 82 m to prevent any risk of short-circuit between two adjacent connection zones. Such a constraint is associated with the fact that during connection, and therefore the insertion of the inserts into the ductile material bumps, the deformation of the ductile material bumps may take place in the direction of adjacent zones and cause connections, i.e. short-circuits, between adjacent ductile material bumps.

It is also known from the document US 2010/207266 to provide a hybridisation barrier to prevent any risk of short-circuit between two adjacent connection zones even for high connection densities.

Nevertheless, the manufacturing method disclosed by the document US 2010/207266 is relatively complex since it requires a large number of deposition steps particularly to form the base, the inserts and the hybridisation barriers and therefore requires costly alignment steps.

### DESCRIPTION OF THE INVENTION

The present invention is intended to remedy this drawback and therefore the aim thereof is therefore more specifically that of providing a method for connecting two components not involving a short-circuit risk between two adjacent connection zones even for high connection densities, said method being simpler than those of the prior art, such as that disclosed by the document US 2010/207266, which does not involve a short-circuit risk between two connection zones.

For this purpose, the invention relates to a hybridisation electrical connection method of a first component to a second component, the first and second component including respectively a first and a second connection face, the first connection face including at least a first and second connection zone to be connected respectively to at least a third and a fourth corresponding connection zone of the second connection face,

the method including the following steps:

formation of a first and a second metallic ductile material bump in respective contact with the first and the second connection zone,

formation of a first and a second insert made of conductive material in contact with respectively the third and the fourth connection zone, the first and the second insert being intended to be inserted into respectively the first and the second ductile material bump, the method further comprising the following steps:

formation on the second connection face of at least a first and a second hybridisation barrier arranged at least in part between the first and the second insert and electrically insulated from one another, said first and second hybridisation barrier being both positioned outside the surfaces projected orthogonally onto the second connection face of the first and second ductile material bumps when the first and the second connection zone are placed facing respectively the third and fourth connection zone, the first and the second hybridisation wall being outside respectively the fourth and the third connection zone,

connection of the first and the second connection zone with respectively the third and the fourth connection zone by inserting the first and the second insert into respectively the first and the second ductile material bump, the first and second connection zones facing the first and second hybridisation barrier acting as a barrier by containing the deformation of respectively the first and the second ductile material bump in the direction of respectively the fourth and the third connection zone.

The first and the second insert being presented in a hollow shape.

the method further including the following step:

connection of the first and the second connection zone with respectively the third and the fourth connection zone by inserting the first and the second insert in respectively the first and the second ductile material bump, the first and second connection zones facing the third and fourth connection zones and the first and second hybridisation barrier acting as a barrier by containing the deformation of respectively the first and the second ductile material bump in the direction of respectively the fourth and the third connection zone.

The step of forming the first and the second insert includes the following substeps:

deposition of a sacrificial layer on the second connection face,

partial etching, of the sacrificial layer so as to release a part of each of the connection zones corresponding to a zone portion intended to be present between the insert and the corresponding hybridisation barrier,

deposition of a layer of a metallic material intended to form the first and the second insert and the first and the second hybridisation barrier,

polishing of the second face so as to remove the part of the layer of metallic material which is in contact with the surface of the sacrificial layer which is opposite the second connection face and retain the parts of the layer of metallic material 320 covering the parts previously released, said retained parts thus forming the conductive elements of the connection zones,

removal of the sacrificial layer.

With such a connection method, there is no risk of short-circuit between the third and the fourth zone regardless of the pitch between the third and the fourth connection zone. Indeed, the first and second hybridisation barriers, by containing the deformation of the ductile material bumps in the direction of the other ductile material bump, removing any risk of direct contact between the first and the second ductile material bump. Furthermore, the first and the second hybridisation barrier being electrically insulated from one another, this insulation makes it possible to electrically insulate the first and the second ductile material bump from one another.

With such hybridisation barriers, it is therefore possible to have a high connection density with no risk of short-circuit between two adjacent connection zones.

Furthermore, with such a method, the hybridisation barriers are formed at the same time as the inserts. This results in a simplified method with respect to those of the prior art for which the hybridisation barriers are formed separately from the inserts.

During the step of formation on the second connection face of at least a first and a second hybridisation barrier, the first and the second hybridisation barrier may be formed respectively in contact with the third and the fourth connection zone.

In this way, the first and second hybridisation barriers being formed respectively in contact with the third and the fourth contact zone, the space between the third and fourth connection zones may be minimised since it is not occupied by the hybridisation barriers.

During the formation of the first and the second hybridisation barrier, the first and second hybridisation barriers may be made of a conductive material.

Thus, the first and the second hybridisation barrier contribute respectively to the electrical connection between the first ductile material bump and the third connection zone and between the second ductile material bump and the fourth connection zone.

The terms “conductive” and “insulating”, when used above and hereinafter in this document, should be understood as “electrical conductor” and “electrical insulator”.

The steps of formation of the first and the second insert and of the first and the second hybridisation barrier may be carried out simultaneously, the first and the second insert and the first and the second hybridisation barrier being made of the same conductive material.

Thus, the electrical connection between the first and the second component may be obtained with a reduced number of steps.

During the formation steps of the first and the second insert and of the first and the second hybridisation barrier, the formation of the first insert and of the first hybridisation barrier consists of the formation of a first conductive element in contact with the third connection zone, the formation of the second insert and of the second hybridisation barrier consists of the formation of a second conductive element in contact with the fourth connection zone.

During the formation steps of the first and the second insert and of the first and the second hybridisation barrier, the first and the second conductive element may each be presented in the form of a first and a second revolving cylindrical and concentric wall, each extending substantially perpendicularly to the corresponding connection zone surface, the first wall being surrounded by the second wall and forming the insert corresponding to said conductive element, the surface of the second wall facing the first wall forming the hybridisation barrier corresponding to said conductive element.

In this way, the deformation of the first and the second ductile material bump takes place in all of the directions of the connection plane of the first and the second component. It is therefore possible to optimise the density of the connections between the first and the second component along all the directions of the connection plane.

The steps of formation of the first and the second insert and of the first and the second hybridisation barrier may comprise the following substeps:

deposition of a sacrificial layer on the second connection face,

partial etching, of the sacrificial layer so as to release a part of each of the connection zones corresponding to the annular base of the conductive element to be formed

deposition of a layer of a metallic material intended to form the conductive elements of the connection zones,

polishing of the second face so as to remove the part of the layer of metallic material which is in contact with the surface of the sacrificial layer which is opposite the second connection face and retain the parts of the layer of metallic material covering the parts previously released, said retained parts thus forming the conductive elements of the connection zones,

removal of the sacrificial layer.

With such steps, it is possible to form the first and the second insert and the second hybridisation barrier using microelectronic techniques, such as the damascene process.

During the step of formation of the first and the second hybridisation barrier, the first and the second hybridisation barrier may surround respectively the first and the second insert.

In this way, the deformation of the first and the second ductile material bump takes place in all of the directions of the connection plane of the first and the second component. It is thus possible to optimise the density of the connections between the first and the second component along all the directions of the connection plane.

According to an option not included within the scope of the invention, during the step of formation of the first and the second insert, there may be formed a first and a second conductive element forming the first and the second insert respectively,

and during the step of formation of the first and the second hybridisation barrier, there may be formed at least a first non-conductive element at least in part positioned between the first and the second insert, said at least a first insulating element including a first surface facing the first insert forming the first hybridisation barrier and a second surface facing the second insert forming the second hybridisation barrier.

The use of such an insulating element makes it possible to obtain satisfactory electrical insulation between the third and the fourth connection zone. The risks of short-circuit between the third and the fourth connection zone are thus particularly low.

The invention also relates to an assembly of two components interconnected by hybridisation,

wherein the first component includes a first connection face comprising at least a first and a second connection zone, each of the first and second connection zone, said first component further including in contact a first and a second ductile material bump in contact respectively with the first and the second connection zone,

wherein the second component includes a second connection face comprising at least a third and a fourth connection zone facing respectively the first and the second connection zone, the second component further including a first and a second insert in contact with respectively the third and the fourth connection zone, the first and second insert being respectively inserted in the first and the second ductile material bump of the first and the second connection zone so as to ensure an electrical connection between the first and the second connection zone and respectively the third and the fourth connection zone,

the second component further including on the second connection face thereof a first and second hybridisation barriers arranged at least in part between the first and the second insert, the first and the second hybridisation wall being outside respectively the fourth and the third connection zone and acting as a barrier to respectively the first and the second ductile material bump in the direction of respectively the fourth and the third connection zone.

The first insert and the first barrier being connected by a first metallic base formed solely therebetween, the second insert and the second barrier being connected by a second metallic base formed solely therebetween.

Such an assembly of components benefits from the advantages associated with the connection method according to the invention and thus unlikely to have short-circuits even with an optimised density of connections between the first and the second components.

The first and second hybridisation barrier and the first and the second insert may be made of a conductive material.

The first insert and the first barrier may be provided by a first conductive element in contact with the first connection zone, the second insert and the second barrier being provided by a second conductive element in contact with the second connection zone.

In this way, the hybridisation barriers may contribute to the connections between the first and the third connection zone and between the second and the fourth connection zone.

According to an option not included within the scope of the invention, the first and the second hybridisation barrier may be provided by at least a first insulating element, said at least a first insulating element including a first surface facing the first insert forming the first hybridisation barrier and a second surface facing the second insert forming the second hybridisation barrier.

Such an insulating element makes it possible to obtain satisfactory electrical insulation between the third and the fourth connection zone. The risks of short-circuit between the third and the fourth connection zone are thus particularly low.

### BRIEF DESCRIPTION OF THE FIGURES

The present invention will be understood more clearly on reading the description of examples of embodiments, given purely by way of indication and in no way limitation, with reference to the appended figures wherein:

FIG. 1 is a schematic sectional view of an assembly of two components interconnected by hybridisation according to a first embodiment of the invention, the first component including two hybridisation contacts, the second component including two conductive elements forming inserts and hybridisation barriers,

FIG. 2 is a schematic perspective view representing solely the second component of the assembly illustrated in FIG. 1,

FIG. 3 is a close-up sectional view of a connection zone of the first and second components of the assembly illustrated in FIG. 1 before connection, FIG. 3 illustrating the design constraints of the hybridisation barriers according to the invention,

FIGS. 4A to 4F illustrate the steps of formation of conductive elements of the second component of the assembly illustrated in FIG. 1,

FIG. 5 illustrates a schematic top view of a second component of an assembly according to this first embodiment of the invention for which twelve connections are envisaged,

FIG. 6 illustrates the main connection steps of the first component with the second component to form an assembly according to this first embodiment, such as that illustrated in FIG. 1,

FIGS. 7A to 7E illustrate schematic sectional views of an assembly and a top view of the second component of the same assembly according to respectively the first to a sixth embodiment of the invention, FIG. 7A corresponding to the assembly according to the first embodiment, FIG. 7B corresponding to an assembly according to a second embodiment not covered by the invention wherein the first and second hybridisation barriers are formed by an insulating conductive element, FIG. 7C corresponds to an assembly according to a fourth embodiment wherein each of the inserts is a bevelled insert, FIG. 7D corresponding to an assembly according to a fifth embodiment not covered by the invention wherein each of the connection zones includes a first and a second cylindrical conductive element of ellipsoid cross-section each contributing to the formation of the insert and of the hybridisation barrier, FIG. 7E corresponding to an assembly according to a sixth embodiment not covered by the invention wherein each of the connection zones includes a conductive element forming the insert and a non-conductive element forming the hybridisation barrier,

FIG. 8 illustrates four top views of different shape configurations for the insert/hybridisation barrier assembly compatible with the first embodiment, the view referenced a) corresponding to inserts and hybridisation barriers of square cross-section, the view referenced b) corresponding to circular inserts and hybridisation barriers of square cross-section, the view referenced c) corresponding to circular inserts and to hybridisation barriers of hexagonal cross-section, the view referenced d) corresponds to solid circular inserts and hybridisation barriers of hexagonal cross-section.

Identical, similar or equivalent parts of the different figures bear the same reference numbers so as to facilitate the transition from one figure to another.

The different parts represented in the figures are not represented necessarily according to a uniform scale, to render the figures more legible.

The different possibilities (alternative embodiments and embodiments) should be understood as not being mutually exclusive and may be combined with one another.

### DETAILED DESCRIPTION OF PARTICULAR EMBODIMENTS

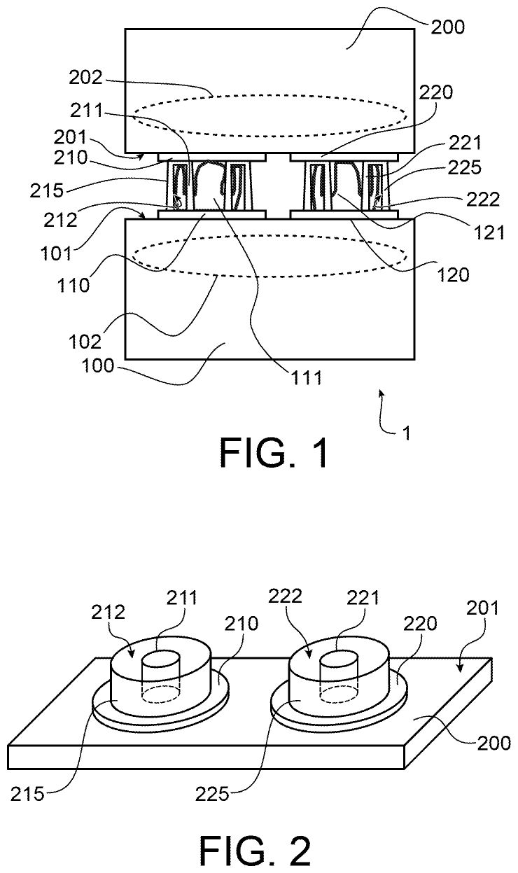

FIG. 1 represents an assembly 1 of two connected components 100, 200 the connection of which has been obtained by means of a method according to a first embodiment of the invention. This first component 100 may thus be, for example, an optical sensor, such as an CCD or CMOS array, or an imager, such as an LCD array, to be connected to a second component, such as optical sensor or imager electronics. Thus, the aim of such a method, as shown in FIG. 1, is that of connecting semiconductor structures 102 of the first component 100 with semiconductor structures 202 of the second component.

The first component 100 may thus include a semiconductor substrate of a first type, such as a III-IV semiconductor material substrate such as a gallium nitride/corundum type substrate, the second component including a semiconductor substrate of a second type, such as a silicon Si or germanium Ge substrate.

To enable the connection of the first and the second component 100, 200, such an assembly 1 of two components 100, 200 includes: the first component 100 including a first connection face 101 comprising at least a first and a second connection zone 110, 120, said first component 100 further including a first and second ductile material bump 111, 121 in contact respectively with the first and the second connection zone 110, 120, the second component 200 including a second connection face 201 comprising at least a third and a fourth connection zone 210, 220 facing respectively the first and the second connection zone 110, 120, the second component 200 further including a first and a second insert 211, 221 in contact with respectively the third and the fourth connection zone 210, 220, the first and the second insert 211, 221 being respectively inserted into the first and the second ductile material bump 111, 121, the second component 200 further including on the second connection face thereof a first and second hybridisation barrier 212, 222 arranged at least in part between the first and the second insert 211, 221 and being electrically insulated from one another, the first and the second hybridisation wall 212, 222 being outside respectively the fourth and the third connection zone 220, 210 and acting as a barrier to respectively the first and the second ductile material bump 111, 121 in the direction of respectively of the fourth and the third connection zone 210, 220.

The first component 100 includes on the first connection face 101 the first and the second connection zone 110, 120. Each of the first and the second connection zone 110, 120 is formed by a metallic layer acting as a contact for the structure 101. If a soldering connection is sought, the metallic layers forming the first and the second connection zone 110, 120 are made of a wettable material with the material of the first and second ductile material bumps 111, 121. Obviously, such a feature is not necessary if a deformation connection is sought.

Each of the metallic layers forming the first and the second connection zone 110, 120 may be made of a material selected from the group including gold Au, aluminium Al, silver Ag, nickel Ni, platinum Pt, palladium Pd and alloys thereof.

According to an option of the invention wherein a soldering connection is sought, said metallic layers forming the first and the second connection zone 110, 120 may be formed from a first metallic sublayer to contact one of the zones of the first structure 102 and a second metallic sublayer covering the first metallic layer and being made of a wettable material with the material from which the ductile material bumps 111, 121 are made.

By wettable material with the material wherein the first and second ductile material bumps 111, 121 are made, it should be understood herein and hereinafter in this document that the wettable material exhibits a total wettability with respect to the material of the ductile material bumps. In other words, the spreading coefficient S of the material of the ductile material bumps, when it is in the liquid state, is strictly positive.

The first and second connection zones 110, 120 are equipped respectively with the first and the second ductile material bump 111, 121. Each of the first and the second ductile material bump 111, 121 is made of a ductile material such as indium. Thus, the material of the first and second ductile material bump 111, 121 may be selected in the group including indium In, tin Sn, aluminium Al, copper Cu, zinc Zn and the alloys thereof, such as tin alloys like lead-tin alloys SnPb and copper-silver-tin alloys SnAgCu.

Thus, if we take the example of a soldering connection, the first and the second ductile material bump may be made of indium In, tin Sn or one of the alloys thereof such as lead-tin alloys SnPb and copper-silver-tin alloys SnAgCu, the first and the second connection zones optionally being made of gold Au.

On the other hand, if we take the example of a connection obtained by deformation, the first and the second ductile material bump may be made of aluminium Al, copper Cu or zinc Zn, the first and the second connection zones optionally being made of aluminium Al, copper Cu or zinc Zn.

It can be seen in FIG. 2 that the second component 200 includes on the second connection face 201 the third and the fourth connection zone 210, 220. Each of these third and fourth connection zones 210, 220 is formed by a metallic layer acting as a contact for the structure 201. If a soldering connection is sought, the metallic layers forming the third and the fourth connection zone 210, 220 are made of a wettable material with the material of the first and second ductile material bumps 111, 121. Each of the metallic layers forming the third and the fourth connection zone 210, 220 may be made of a material selected from the group including gold Au, aluminium Al, silver Ag, nickel Ni, platinum Pt, palladium Pd and alloys thereof.

Obviously, according to an option of the invention not illustrated wherein a soldering connection is sought, and similarly to the first and second connection zones 110, 120, the metallic layers forming the third and the fourth connection zones 210, 220 may also be formed from a first metallic sublayer to contact one of the zones of the second structure 202 and a second metallic sublayer covering the first metallic layer and being made of a wettable material with the material from which the ductile material bumps 111, 121 are made.

The third and the fourth connection zone 210, 220 are respectively equipped with a first and a second conductive element 215, 225. The first element 215 includes both the first insert 211 and the first hybridisation barrier 212, whereas the second element 225 includes both the second insert 221 and the second hybridisation barrier 222. The first and the second conductive element 215, 225, as shown in FIG. 2, each being presented in the form of a first and a second revolving cylindrical and concentric wall and which extend perpendicularly to the surface of the corresponding connection zone 210, 220. Thus, the first and the second cylindrical wall of each of the first and second conductive elements 215, 225 have the axis of revolution thereof perpendicular to said surface of the corresponding connection zone 210, 220. For each of the first and second conductive elements 215, 225, the first wall is inside the second wall, i.e. it is surrounded by the second wall. Each of the first and second conductive elements 215, 225 also includes an annular base in contact with the corresponding connection zone 210, 220 and interconnecting the first and the second wall of said conductive element 215, 225.

The first and second conductive elements 215, 225 are made of a metallic material selected in the group including copper Cu, Titanium Ti, tungsten W, Chromium Cr, nickel Ni, platinum Pt, palladium and alloys thereof, such as tungsten silicide WSi, tungsten nitride WN and titanium nitride TiN. According to an advantageous option of the invention, the metallic material of the first and second conductive element 215, 225 is copper Cu.

According to an option of the invention, each of the conductive elements 215, 225 may further include a metallic coating, such as a gold layer, so as to protect from oxidation the metallic material from which it is made.

The first and the second conductive element 215, 225 are designed such that:

the first wall of the first and the second conductive element 215, 225 are arranged inside a surface corresponding respectively to the surface projected orthogonally from the first and the second ductile material bump 111, 121 when the first and the second connection 110, 120 are placed facing respectively the third and the fourth connection zone 210, 220,

the second wall of the first and the second conductive element are arranged outside a surface corresponding respectively to the surface projected orthogonally from the first and the second ductile material bump 111, 121 when the first and the second connection zone 110, 120 are placed facing respectively the third and the fourth connection zone 210, 220.

It shall be noted furthermore that the first and the second conductive element 215, 225, being formed in contact with respectively the third and the fourth connection zone 210, 220, the second wall of the first and the second conductive element 215, 225, by such a design, is outside respectively the fourth and the third connection zone 220, 210. Similarly, the first and second conductive elements 215, 225 are at a distance from one another, without there being any electrical connection therebetween. The first and the second conductive elements are therefore electrically insulated from one another. Thus, the first and second hybridisation barriers 212, 222, formed respectively by the second wall of the first and the second conductive element 215, 225, are also electrically insulated from one another.

Thus, with such a design and as illustrated in FIG. 1, the first wall of the first and the second conductive element 215, 225 form respectively the first and the second insert 211, 221, and the inner surface of the second wall of the first and the second conductive element 215, 225 form respectively the first and the second hybridisation barrier 212, 222.

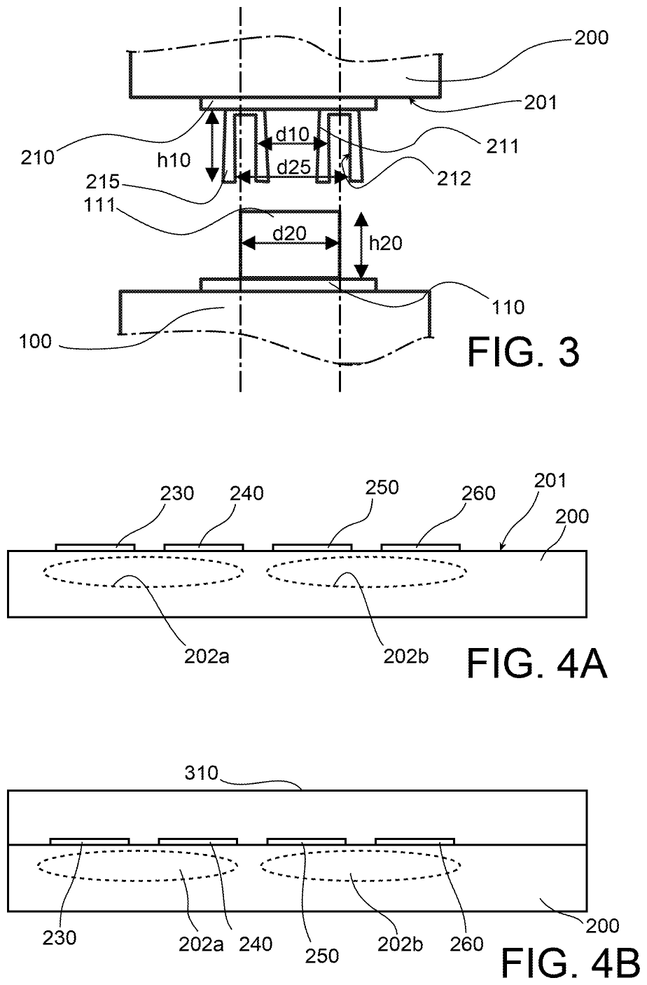

It shall be noted that in practical terms and as illustrated in FIG. 3, such design conditions may generally be obtained by meeting the following conditions:

(1) d10<d20<d25

(2) h10˜h20,

d10 and d25, being respectively the external diameter of the first wall and the internal diameter of the second wall of said conductive element 215, 225 from the first and the second conductive element 215, 225, h10 the height of said first and second wall, d20, h20 the maximum lateral dimension and the maximum height of the ductile material bump 111, 121 corresponding to said conductive element 215, 225. Obviously, these dimensions with respect to the ductile material bumps 111, 121, correspond to the dimensions thereof prior to connection of the first component 100 with the second component 200, the ductile material bump 111, 121 being subject to deformation during connection. Similarly, such a design applies for a configuration wherein during the assembly of the first and the second component 100, 200, the ductile material bump 111, 121 is placed facing the corresponding conductive element. The external diameter d10 of the first wall and the internal diameter d25 of the second wall of the first and second conductive elements 215, 225 may obviously be chosen to compensate for any misalignment between the conductive element 215, 225 and the corresponding ductile material bump 111, 121, by undersizing the external diameter of the first wall and oversizing the internal diameter of the second wall with respect to the dimensions of the ductile material bump 111, 121.

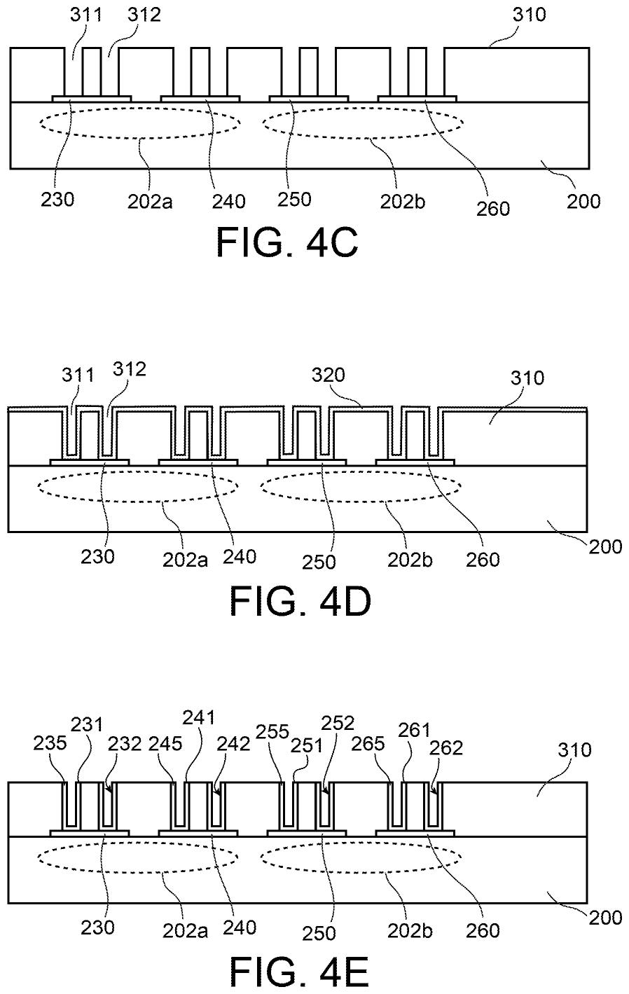

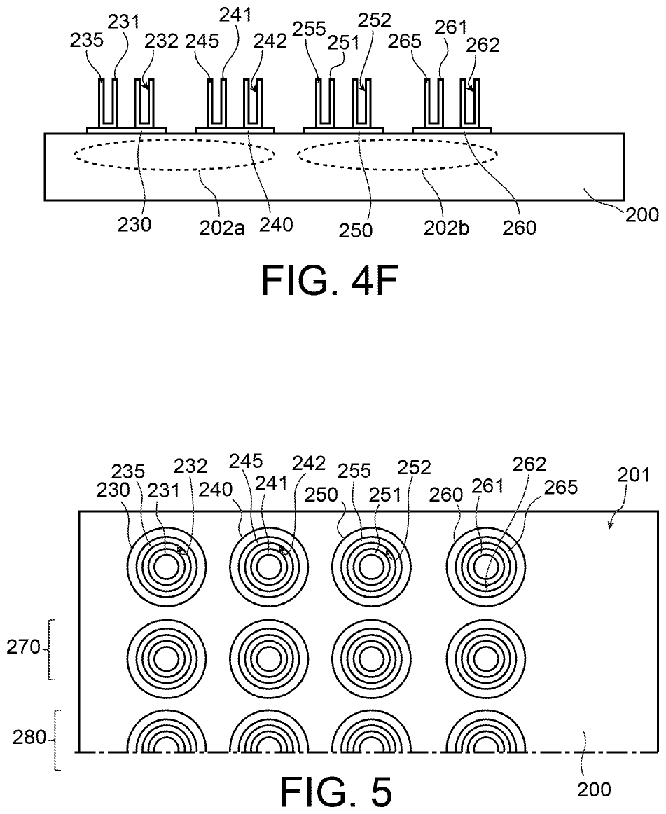

FIGS. 4A to 4E illustrate a method for forming conductive elements 235, 245, 255, 265, on the connection zones 230, 240, 250, 260 of a second component 200 according to this first embodiment, said component which comprises two second structures 202a, 202b, each connected by means of two respective connection zones 230, 240, 250, 260. Such a formation method includes the following steps:

provision, as illustrated in FIG. 4A of the second component 200, of each of the connection zones 230, 240, 250, 260 formed by a respective metallic layer,

deposition, as illustrated in FIG. 4B, of a sacrificial layer 310 intended to form a hard mask, said sacrificial layer having a thickness greater than the height h10 sought for the first and second of the conductive elements 215, 225 to be formed,

partial etching, as illustrated in FIG. 4C, of the sacrificial layer 310 so as to release the part 311, 312 of each of the connection zones 320 corresponding to the annular base of the conductive elements to be formed,

deposition, as illustrated in FIG. 4D, of a layer of the metallic material 320 intended to form the conductive elements 235, 245, 255, 265 of the connection zones 230, 240, 250, 260,

polishing, as illustrated in FIG. 4E, of the layer of the metallic material 320 and of a part of the sacrificial layer 310 so as to remove the part of the layer of the metallic material 320 covering the sacrificial layer 310 and retain the parts of the layer of the metallic material covering the parts 311 previously released, said parts of the layer of the metallic material 320 retained thus forming the conductive elements 235, 245, 255, 265 of the connection zones 230, 240, 250, 260,

removal of the sacrificial layer 310, as illustrated in FIG. 4F.

It is to be noted that such a method, particularly if the materials of the sacrificial layer 310 and of the layer of the metallic material 320 are respectively silicon dioxide SiO₂ and copper Cu, offers the advantage of making use of a perfectly mastered conventional technique of the microelectronics industry such as the damascene etching technique. It is thus possible to embody with such a method second components comprising a large number of connection zones 230, 240, 250, 260, 270, 280 organised, for example and as illustrated in FIG. 5, in the form of an array with an optimised connection density. The design and positioning of these connection zones are then controlled at the scale of around one hundred nanometres and it is possible to envisage pitches between the zones less than 5 82 m.

Indeed, it is possible to take the example for such a pitch of 5 82 m, of a WUXGA format screen, i.e. having a resolution of 1920×1080 and requiring more than 2 million connections, made of a gallium nitride GaN by way of first component 100 to be connected to a second component 200 which is a silicon CMOS technology control circuit. To enable the connection of this screen by way of first component 100, each of the connection zones 111 of the first component 100 may be equipped, with reference to FIG. 3, with a respective ductile material bump 111 having a diameter d20 of 3 82 m and a height h20 of 2.5 °m. The control circuit may in turn include on each of these connection zones 210 a conductive element 215 of a height of 2.5 °m and wherein the external diameter of the insert and internal diameter of the hybridisation barrier d25, d10 are respectively equal to 1.5 °m and 3.5 °m.

In this way, the equations (1) and (2) being observed, the more than 2 million connections between the screen and the control circuit may be made with a pitch of 5 82 m with no risk of short-circuit between two adjacent connection zones, by means of the hybridisation barriers which will help contain the deformation of the ductile material bumps 211, 221.

The first and second components 100, 200 according to this first embodiment may be interconnected according to a connection method. Such a connection method comprises the following steps:

formation of the first and the second ductile material bump 111, 121 in respective contact with the first and the second connection zone 110, 120,

formation of the first and second conductive elements in contact with respectively the third and the fourth connection zone 210, 220 so as to thus form the first and the second insert 211, 221 made of conductive material, and the first and the second hybridisation barrier 212, 222 arranged at least in part between the first and the second insert and electrically insulated from one another,

connection of the first and the second connection zone 110, 120 with respectively the third and the fourth connection zone 210, 220 by inserting the first and second insert 211, 221 into respectively the first and the second ductile material bump 111, 121, the first and second connection zones 110, 120 facing the third and fourth connection zones 210, 220 and the first and second hybridisation barriers 212, 222 acting as a barrier by containing the deformation of respectively the first and the second ductile material bump 111, 121 in the direction of respectively the fourth and the third connection zone 220, 210.

The step of providing the first and second conductive element 215, 225 may be a step of using the method for manufacturing the second component 200 previously described.

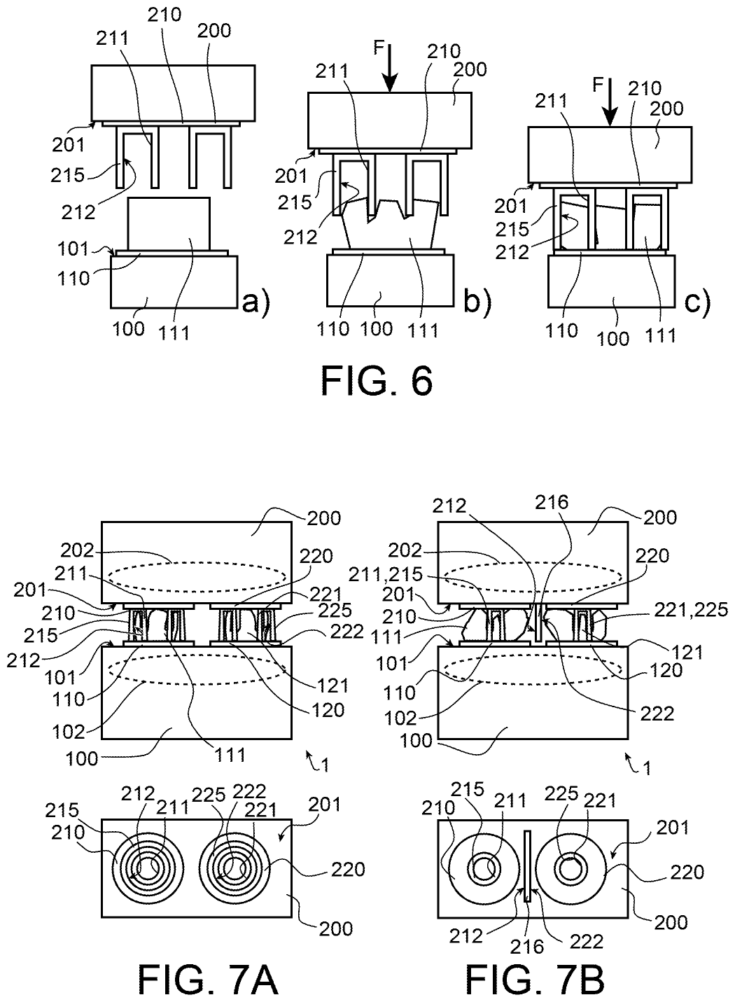

The connection step is ideally a connection step comprising two compression substeps, such as those described in the document WO2009/115686. Such substeps are, with reference to FIG. 6:

alignment of the first and second components 100, 200 so as to place the first the second connection zone 110, 120 facing respectively the third and the fourth connection zone 210, 220, as illustrated in a) in FIG. 6,

partial insertion of the first and second inserts 211, 221 into respectively the first and the second ductile material bump 111, 121, as illustrated in b) in FIG. 6,

final insertion of the first and second inserts 211, 221, into respectively the first and the second ductile material bump 111, 121, as illustrated in c) in FIG. 6.

It can be noted that in order to reduce the thermal impact and prevent air being trapped between each of the ductile material bumps 111, 121 and the corresponding insert 211, 212, the two insertion substeps may be carried out at ambient temperature and the final insertion step may be carried out in a low-pressure environment such as in a primary vacuum (i.e. a pressure between 1000 and 1.10⁻³ mbar).

It shall be noted that the alignment being obtained prior to the partial insertion and being sustained by the partial insertion, the final insertion step may be carried out by means of a press devoid of an alignment system.

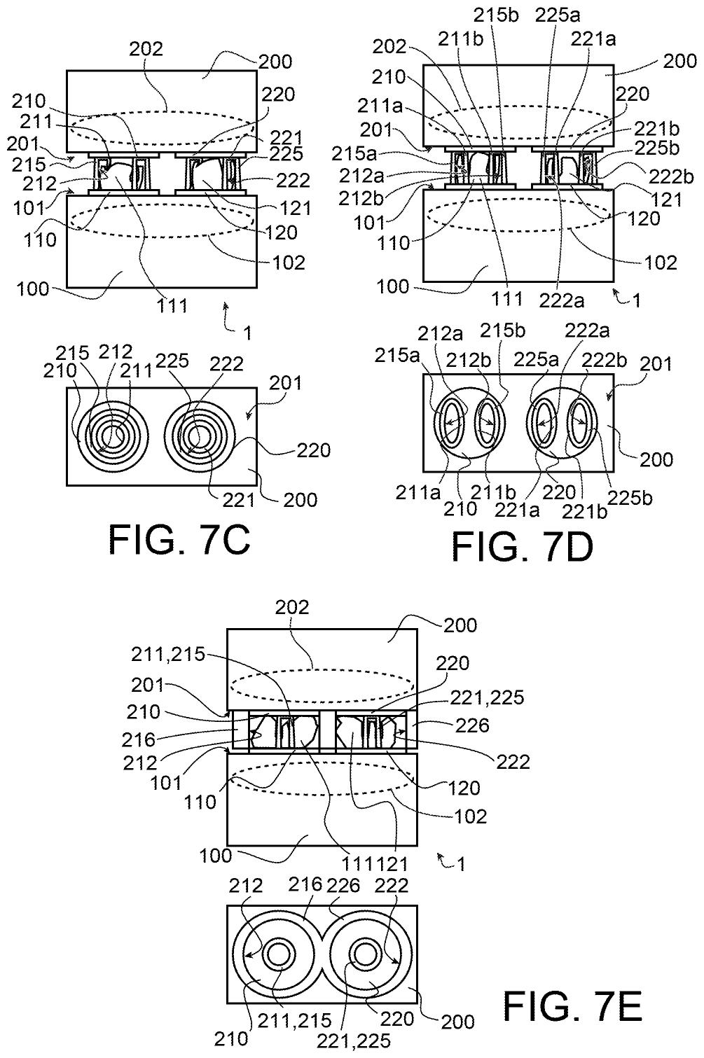

FIGS. 7A to 7E illustrate different embodiments of the invention which are differentiated essentially by the shape of the first and second hybridisation barriers 212, 222 and the first and second inserts 211, 221, some of these embodiments not being covered by the invention.

Thus, figure7A illustrates an assembly 1 according to the first embodiment with above a schematic sectional view of the assembly 1 and below a top view of the second component 200. This figure being similar to FIGS. 1 to 3, we refer the reader to the description previously made.

FIG. 7B illustrates an assembly 1 according to a second embodiment not covered by the invention wherein the first and second hybridisation barriers 212, 222 are provided by means of a non-conductive element 216, the inserts 211, 221 being for their part provided by a conductive element 215, 225 according to the principle described in the document WO2009/115686. Such an assembly 1 according to this second embodiment is differentiated from an assembly 1 according to the first embodiment by the shape of each of the conductive elements 215, 225 providing the inserts 211, 221 and by a presence of a non-conductive element 216 providing the first and the second hybridisation barrier 212, 222.

In this second embodiment not covered by the invention, the non-conductive element 216 is a wall made of an electrically insulating material, such as for example that forming the sacrificial layer 310 during the formation of the conductive elements 215, 225, arranged between the third and the fourth connection zone 210, 220. The surface of the non-conductive element 216 facing the third connection zone 210 thus forms the first hybridisation barrier 212 whereas the other surface, which is therefore facing the fourth connection zone 220, forms the second connection barrier 222.

The non-conductive element 216 being made of an electrically insulating material, the first and the second hybridisation barrier are electrically insulated with respect to one another. Therefore, there is no risk of short-circuit between the first and the second ductile material bump 111, 121 when these first and second hybridisation barriers 212, 222 contain the deformation of the ductile material bumps 111, 121.

The first and second conductive elements 215, 225 being of the same type as the inserts described in the document WO2009/115686, the first and second conductive elements 215, 225 are arranged on a surface corresponding respectively to the surface projected orthogonally from the first and the second ductile material bump 111, 121 when the first and the second connection zone 110, 120 are placed facing respectively the third and the fourth connection zone 210, 220.

The non-conductive element 216, being arranged outside the third and fourth connection zones 210, 220, is outside the surface projected orthogonally from the first and the second ductile material bump 111, 121 when the first and the second connection zone 110, 120 are placed facing respectively the third and the fourth connection zone 210, 220.

The formation method of the conductive elements 215, 225 and of the non-conductive element 226 of a second component 200 according to this second embodiment not covered by the invention is differentiated from the formation method of the conductive elements 215, 225 according to the first embodiment in that during the step of removing the sacrificial layer 310, the removal is merely partial, a part of the sacrificial layer 310 being retained to form the non-conductive element 216.

FIG. 7C illustrates an assembly 1 according to a third embodiment wherein each of the first and second conductive elements 215, 225 has the bevelled internal portion thereof so as to favour the insertion of each of the first and second inserts 211, 221 into the corresponding ductile material bump 111, 112. An assembly according to this fourth embodiment is differentiated from an assembly according to the first embodiment by the bevelled shape of the internal portion of each of the first and second conductive elements 215, 225.

Thus, each of the first and second conductive elements 215, 225 has the bevelled internal cylinder portion. The corresponding insert 211, 221 is thus also bevelled according to a similar principle to that described in the document WO2009/115686 and the force required for the connection of the first and the second component 100, 200 is lowered.

FIG. 7D illustrates an assembly 1 according to a fourth embodiment of the invention not covered by the invention wherein each of the third and fourth connection zones 210,220 is equipped with two conductive elements 215a, 215b, 225a, 225b. An assembly 1 according to this fourth embodiment is differentiated from an assembly 1 according to the first embodiment in that there is envisaged a first and a second conductive element 215a, 215b in contact with the first connection zone 210 and a third and a fourth conductive element 225a, 225b in contact with the second connection zone 220, and in that the first, second, third and fourth conductive elements 215a, 215b, 225a, 225b have a cylindrical shape of elliptical cross-section. The first, second, third and fourth conductive elements 215a, 215b, 225a, 225b are presented each in the form of a cylindrical casing of elliptical cross-section, the axis of the foci being substantially perpendicular to a line passing through the third and fourth connection zone 210, 220.

The first and the second conductive element 215a, 215b are arranged according to a central symmetry with respect to the centre of the first connection zone 210. In this way, the proximal wall of each of the first and second conductive elements in respect of the centre of the first connection zone 210 forms the first insert 211, whereas the distal wall of each of the first and second conductive elements 215a, 215b in respect of the centre of the first connection zone 210 forms the first hybridisation barrier 212.

In the same way, the third and the fourth conductive element 225a, 225b are arranged according to a central symmetry with respect to the centre of the second connection zone 220. The proximal wall of each of the third and fourth conductive elements 225a, 225b, in respect of the first connection zone 210, forms the second insert 221, whereas the distal wall of each of the third and fourth conductive elements, in respect of the centre of the second connection zone 220, forms the second hybridisation barrier 222.

The design of the first to the fourth conductive element 215a, 215b, 225a, 225b is adapted so that:

the proximal wall portions of the first, second, third and fourth conductive element 215a, 215b, 225a, 225b are arranged inside a surface corresponding, for the first and second conductive elements 215a, 215b, to the surface projected orthogonally from the first ductile material bump 111, and for the third and fourth conductive elements 225a, 225b to the surface projected orthogonally from the second ductile material bump 121, when the first and the second connection zone 110, 120 are placed facing respectively the third and the fourth connection zone 210, 220,

the distal wall portions of the first, second, third and fourth conductive element 215a, 215b, 225a, 225b are arranged outside a surface corresponding, for the first and second conductive elements 215a, 215b to the surface projected orthogonally from the first ductile material bump 111, and, for the third and fourth conductive elements 215a, 225b to the surface projected orthogonally from the second bump 121, when the first and the second connection zone 110, 120 are placed facing respectively the third and the fourth connection zone 210, 220.

The formation method of the connection elements 215a, 215b, 225a, 225b according to this fourth embodiment not covered by the invention may be a method of the same type as that described in the document WO2011/115686, the shape and the positioning of the inserts formed during the method described in the document WO2011/115686 merely having to be adapted to correspond to those of the connection elements 215a, 215b, 225a, 225b according to this embodiment.

FIG. 7E illustrates an assembly 1 according to a fifth embodiment not covered by the invention wherein the first and the second connection zone 110, 120 are surrounded respectively by a first and a second non-conductive element 216, 226 and are in contact with respectively a first and a second conductive element 215, 225. An assembly according to this fifth embodiment is differentiated from an assembly according to the first embodiment in that it includes a first and a second non-conductive element 216, 226 forming respectively the first and the second hybridisation barrier 212, 222, the first and the second conductive element 215, 225 forming the first and the second insert 211, 221.

In this fifth embodiment not covered by the invention, the first and the second connection zone 210, 220 are surrounded respectively by the first and the second non-conductive element 216, 226. Each of the first and second non-conductive elements 216, 226 is formed by a wall made of non-conductive material. According to one advantageous option of this embodiment, and when the material of the sacrificial layer 310 is insulating, each of the first and the second insulating element 216, 226 is made of the same material as that of the sacrificial layer.

In the same way as the second embodiment not covered by the invention, the first and the second conductive element 215, 225 are of the same type as those of the second embodiment. Thus, the first and second elements are arranged on a surface corresponding respectively to the surface projected orthogonally from the first and the second ductile material bump 111, 121 when the first and the second connection zone 110, 120 are placed facing respectively the third and the fourth connection zone 210, 220.

The non-conductive elements 216, 226 being arranged outside the first and second connection zone 210, 220, are also outside the surface projected orthogonally from the first and the second ductile material bump 111, 121 when the first and the second connection zone 110, 120 are placed facing respectively the third and the fourth connection zone 210, 220.

The formation method of the conductive elements 215, 225 and of the non-conductive elements 216, 226 of a second component 200 according to this fifth embodiment not covered by the invention is similar to the formation method according to the second embodiment. Thus, the formation method of the conductive elements 215, 225 and of the non-conductive elements 216, 226 is differentiated from a formation method of the conductive elements 215, 225 according to the second embodiment in that during the step of removing the sacrificial layer 310, the removal is merely partial, parts of the sacrificial layer 310 being retained to form the first and the second non-conductive element 216, 226.

While in the different embodiments described above, the conductive and insulating elements are of revolving cylindrical shape or of elliptical cross-section, the invention is not limited to only these types of shape. Thus the invention covers any type of shape as long as each of the connection zones of the second component includes:

an insert 211, 221 is inserted into a corresponding ductile material bump 111, 121 of the first component 100,

at least one hybridisation barrier 212, 222 positioned outside the surfaces projected orthogonally on the second connection face of the corresponding ductile material 111, 121 when the connection zone 210, 220 is placed facing the corresponding connection zone 110, 120 of the first component 100

the first and the second barrier 212, 222, 232, 242, 252, 262 surrounding respectively the first and the second insert 211, 221, 231, 241, 251, 261, the first insert and the first barrier being connected by a first metallic base formed solely between the latter two, the second insert and the second barrier being connected by a second metallic base formed solely between the latter two.

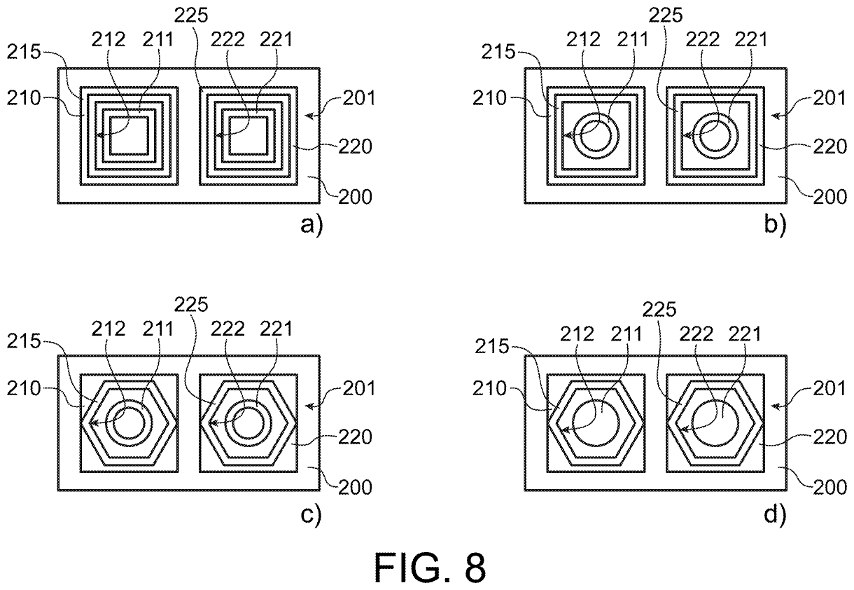

Thus, FIG. 8 illustrates four examples of insert shapes 211, 221 and hybridisation barriers 212, 222 compatible with the invention. In a) of FIG. 8, the insert 211, 221 and the hybridisation barrier 212, 222 are provided by a conductive element 215, 225 presented in the form of a double-walled cylindrical casing of cubic cross-section.

In b) of FIG. 8, the insert 211, 221 is provided by a cylindrical casing of circular cross-section whereas the hybridisation barrier 212, 222 is provided by a cylindrical casing of square cross-section, each of these casings being provided, for a connection zone 210, 220, by a single conductive element 215.

In c) of FIG. 8, the insert 211, 221 is provided by a solid cylinder of circular cross-section whereas the hybridisation barrier 212, 222 is provided by a cylindrical casing of hexagonal cross-section, each of these casings being provided, for a connection zone 210, 220, by a single conductive element 215.

In d) of FIG. 8, the insert 211, 221 is provided with a solid cylinder of circular cross-section whereas the hybridisation barrier 212, 222 is provided by a cylindrical casing of hexagonal cross-section, each of this cylinder and this casing being provided, for a given connection zone 210, 220, by a single conductive element 215.

What is claimed is:

1-9. (canceled)

10. A hybridisation electrical connection method of a first component to a second component, the first component including a first connection face and the second component including a second connection face, the first connection face including at least a first connection zone and a second connection zone to be connected respectively to at least a third connection zone and a fourth corresponding connection zone of the second connection face,
the hybridisation electrical connection method including the following steps:
formation of a first metallic ductile material bump and a second metallic ductile material bump in respective contact with the first connection zone and the second connection zone,
formation of a first insert and a second insert made of conductive material in contact with respectively the third connection zone and the fourth connection zone, the first insert and the second insert being intended to be inserted into respectively the first ductile material bump and the second ductile material bump, the first insert and the second insert being presented in a hollow shape,
wherein, during the formation step of the first insert and of the second insert there is also formed on the second connection face at least a first hybridisation barrier and a second hybridisation barrier arranged at least in part between the first insert and the second insert and electrically insulated from one another, said first hybridisation barrier and second hybridisation barrier being both positioned outside the surfaces projected orthogonally onto the second connection face of the first ductile material bumps and second ductile material bumps when the first connection zone and the second connection zone are placed facing respectively the third connection zone and fourth connection zone, the first hybridisation barrier and the second hybridisation barrier being outside respectively the fourth connection zone and the third connection zone, the first hybridisation barrier and the second hybridisation barrier surrounding respectively the first insert and the second insert,
the method hybridisation electrical connection further including the following step:
connection of the first connection zone and the second connection zone with respectively the third connection zone and the fourth connection zone by inserting the first insert and the second insert into respectively the first ductile material bump and the second ductile material bump, the first connection zone and second connection zone facing the third connection zone and fourth connection zone and the first hybridisation barrier and second hybridisation barrier acting as a barrier by containing the deformation of respectively the first ductile material bump and the second ductile material bump in the direction of respectively the fourth connection zone and the third connection zone,
and wherein the step of forming the first insert and the second insert includes the following substeps:
deposition of a sacrificial layer on the second connection face,
partial etching, of the sacrificial layer so as to release a part of each of the third connection zone and of the fourth connection zone corresponding to a zone portion intended to be present between the insert and the corresponding hybridisation barrier,
deposition of a layer of a metallic material intended to form the first insert, the second insert, the first hybridisation barrier and the second hybridisation barrier,
polishing of the second connection face so as to remove the part of the layer of metallic material which is in contact with the surface of the sacrificial layer of each of the third connection zone and of the fourth connection zone which is opposite the second connection face, and retain the parts of the layer of metallic material covering the parts of each of the third connection zone and of the fourth connection zone previously released, said retained parts of the layer of metallic material thus forming a first conductive element and a second conductive element of respectively the first connection zone and the second connection zone, the first conductive element forming the first insert and the first hybridisation barrier, the second conductive element forming the second insert and the second hybridisation barrier
removal of the sacrificial layer.

11. The electrical connection method according to claim 10 wherein during the step of formation on the second connection face of at least a first hybridisation barrier and a second hybridisation barrier, the first hybridisation barrier and the second hybridisation barrier are formed respectively in contact with the third connection zone and the fourth connection zone.

12. The electrical connection method according to claim 10 wherein during the formation steps of the first insert and the second insert and of the first hybridisation barrier and the second hybridisation barrier, the first conductive element and the second conductive element each being presented in the form of a first evolving cylindrical and concentric wall and a second revolving cylindrical and concentric wall, each extending substantially perpendicularly to the corresponding connection zone surface, the first wall being surrounded by the second wall and forming the insert corresponding to said conductive element, the surface of the second wall facing the first wall forming the hybridisation barrier corresponding to said conductive element.

13. An assembly of a first component and a second component interconnected by hybridisation,
wherein the first component includes a first connection face comprising at least a first connection zone and a second connection zone, said first component further including a first ductile material bump and a second ductile material bump in contact respectively with the first connection zone and the second connection zone,
wherein the second component includes a second connection face including at least a third connection zone and a fourth connection zone facing respectively the first connection zone and the second connection zone, the second component further including a first insert and a second insert in contact with respectively the third connection zone and the fourth connection zone, the first insert and second insert being respectively inserted in the first ductile material bump and the second ductile material bump so as to ensure an electrical connection of the first connection zone and the second connection zone to respectively the third connection zone and the fourth connection zone, the first insert and the second insert being presented in a hollow shape,
wherein the second component further includes on the second connection face thereof a first hybridisation barriers and second hybridisation barriers) arranged at least in part between the first insert and the second insert, the first hybridisation barrier and the second hybridisation barrier being outside respectively the fourth connection zone and the third connection zone and acting as a barrier to respectively the first ductile material bump and the second ductile material bump in the direction of respectively the fourth connection zone and the third connection zone, the first hybridisation barrier and the second hybridisation barrier surrounding respectively the first insert and the second insert, the first insert and the first hybridisation barrier being connected by a first metallic base formed solely therebetween, the second insert and the second hybridisation barrier being connected by a second metallic base formed solely therebetween,
wherein the first insert and the first hybridisation barrier are provided by a first conductive element in contact with the first connection zone, the second insert and the second barrier being provided by a second conductive element in contact with the second connection zone.
